(19) United States
(12) Patent Application Publication
(10) Pub. No.: US 2026/0092971 A1
(43) Pub. Date: Apr. 2, 2026

(54) METHOD AND APPARATUS FOR DETERMINING SETTLING OF ANALOG SIGNAL IN SEMICONDUCTOR DEVICE TESTING

(71) Applicant: Xcerra Corporation, Norwood, MA (US)

(72) Inventor: Stefen Boyd, Beaverton, OR (US)

(21) Appl. No.: 18/900,305

(22) Filed: Sep. 27, 2024

(51) Int. Cl. G01R 31/3183; G01R 31/319

(52) U.S. Cl. CPC G01R 31/318392; G01R 31/31905; G01R 31/31924

(57) ABSTRACT

In an aspect, a method of detecting settling of an analog electrical signal in semiconductor device testing includes providing in a semiconductor device tester a device under test (DUT); providing an input signal to the DUT and measuring the input signal; tracking the measurements over time by overlapping the measured input signal with sequential measurement windows that do not overlap with each other, each measurement window spanning a constant measurement period and a constant signal value range while shifting according to measured changes in the input signal such that each measurement window overlaps at least a portion of the measured input signal corresponding to a preceding measurement window; setting a settle count representing a number of consecutive and unshifted measurement windows having unshifted constant signal value ranges; setting a settle count representing a number of consecutive and unshifted measurement windows having unshifted constant signal value ranges; and determining that a settle point has been reached after detecting that the settle count has been met or exceeded by the measured input signal tracked by the sequential measurement windows. Aspects also include an apparatus for adapted performing the aforementioned method and a non-transitory computer storage medium containing instructions that when read by one or more computer processors perform the aforementioned method.

### BACKGROUND

### Field

The disclosed technology generally relates to systems and methods for testing of electronic devices. More particularly, embodiments relate to a system for monitoring a test input signal to be connected to a semiconductor device being tested in a semiconductor tester and determining when the input signal settles.

### Description of the Related Art

A semiconductor device tester is used to test integrated circuit (IC) devices during or after fabricating the IC devices. The semiconductor device tester conducts testing based on predetermined settings which are dependent upon the characteristics of each device input into the semiconductor device tester for testing. During testing, various testing conditions are applied to the input device and the result is recorded.

The semiconductor device being tested, often referred to as device under test (“DUT”), is subjected to various input signals which may determine functionalities and performance of the DUT. During electrical testing, the electric devices may be first electrically connected to a contactor which includes a set of pins for delivering the input signals to the DUT. These pins come into contact with the input leads of the DUT.

During testing, upon applying an input signal to the DUT, the input signal can vary during a period of settling, during which the measured input signal can experience significant change over time.

### SUMMARY

In an aspect, a method of detecting settling of an analog electrical signal in semiconductor device testing includes providing in a semiconductor device tester a device under test (DUT), providing an input signal to the DUT and measuring the input signal and tracking the measured input signal over time with sequential measurement windows that do not overlap with each other. Each measurement window spans a constant measurement period and a constant signal value range while shifting according to changes in the measured input signal such that each measurement window overlaps at least a portion of the measured input signal corresponding to a preceding measurement window. The method additionally includes setting a settle count representing a number of consecutive and unshifted measurement windows having unshifted constant signal value ranges. The method further includes determining that a settle point has been reached upon detecting that the settle count has been met or exceeded by the measured input signal tracked by the sequential measurement windows.

In another aspect, a semiconductor testing apparatus is configured for detecting settling of an analog electrical signal during semiconductor device testing. The apparatus includes a semiconductor device tester configured to receive therein a device under test (DUT). The apparatus additionally includes an input signal source configured to provide an input signal to the DUT and a signal measurement sensor configured to measure the input signal. The signal measurement sensor is configured to monitor for settling of an electrical signal by directly measuring the input signal. The apparatus additionally includes a detection circuitry configured to receive a measured input signal from the signal measurement sensor. The apparatus additionally includes a non-transitory computer storage medium storing instructions that when executed by one or more processors, causes the one or more processors to perform operations. The operations include tracking the measured input signal over time with sequential measurement windows that do not overlap with each other. Each measurement window spans a constant measurement period and a constant signal value range while shifting according to changes in the measured input signal such that each measurement window overlaps at least a portion of the measured input signal corresponding to a preceding measurement window. The operations additionally include setting a settle count representing a number of consecutive and unshifted measurement windows having unshifted constant signal value ranges and determining that a settle point has been reached upon detecting that the settle count has been met or exceeded by the measured input signal tracked by the sequential measurement windows.

In another aspect, a non-transitory computer storage medium stores instructions that when executed by one or more processors, cause the one or more processors to perform operations. The operations include detecting in a semiconductor device tester a device under test (DUT) provided therein and providing an input signal to the DUT and measuring the input signal. The operations additionally include tracking the measured input signal over time with sequential measurement windows that do not overlap with each other. Each measurement window spans a constant measurement period and a constant signal value range while shifting according to changes in the measured input signal such that each measurement window overlaps at least a portion of the measured input signal corresponding to a preceding measurement window. The operations additionally include setting a settle count representing a number of consecutive and unshifted measurement windows having unshifted constant signal value ranges and determining that a settle point has been reached upon detecting that the settle count has been met or exceeded by the measured input signal tracked by the sequential measurement windows.

### BRIEF DESCRIPTION OF THE DRAWINGS

Embodiments of this disclosure will be described, by way of non-limiting example, with reference to the accompanying drawings.

FIG. 1 is a schematic diagram of a semiconductor device tester.

FIG. 2 is a schematic diagram of a semiconductor device tester electrically connected to a system for monitoring for settling of an input signal, according to embodiments.

FIG. 3A is a graph of an example measured input signal which settles relatively quickly.

FIG. 3B is a graph of an example measured input signal which settles relatively slowly.

FIG. 3C is a graph depicting an example measured input signal with a settle count set as measurement progresses.

FIG. 3D is a graph depicting an example measured input signal with an expected value range set as measurement progresses and the measured input signal overshoots a settle value.

FIG. 3E is a graph depicting an example measured input signal with an expected value range set as measurement progresses and the measured input signal undershoots a settle value.

FIG. 4 is a flowchart illustrating a method of detecting settling of an analog electrical signal in semiconductor device testing, according to embodiments.

FIG. 5 is a flow chart illustrating a method of detecting settling of an analog electrical signal in semiconductor testing while dynamically adjusting a settle count as measurements progress and which accommodates an expected value range, according to some embodiments.

FIG. 6 is a flow chart illustrating a method of detecting settling of an analog electrical signal in semiconductor testing while dynamically adjusting an expected value range as measurements progress, according to some embodiments.

FIG. 7 is a schematic diagram depicting a computer system adapted for detecting input signal settling.

### DETAILED DESCRIPTION

The following detailed description of certain embodiments presents various descriptions of specific embodiments. However, the innovations described herein can be embodied in a multitude of different ways, for example, as defined and covered by the embodiments. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the illustrated elements. Further, some embodiments can incorporate any suitable combination of features from two or more drawings.

In semiconductor device parametric testing, an input signal is applied to a DUT from an input signal source. The input signal from the input signal source can have transient and unstable phases, especially in the beginning. A transient input signal can result in unreliable output signal. Thus, prior to measuring/testing the DUT for data collection, the input signal can be measured to determine if the signal is in a transient phase. After an input signal is generated and connected to the DUT, the measured input signal may initially undergo a transient period in which the input signal, e.g., voltage or current, can vary significantly before attaining a steady-state condition. The transient period can occur for a relatively short duration immediately after generating the input signal. The duration of the transient signal can be in the range of microseconds to several milliseconds and depends on circuit parameters such as resistance, inductance, capacitance, etc. The source of the transient signal can be external to the DUT, e.g., the semiconductor tester, or can be internal to the DUT. The magnitude of the transient voltage and currents can keep changing until a steady-state is achieved. The transient period represents an unstable system, and measurements taken during the transient period can lead to unreliable parametric characterization of the DUT. Efficiently detecting when the transient period has ended can directly impact testing duration, which in turn directly impacts cost. Thus, there is a need for methods and systems for efficiently determining when the transient period has ended to collect reliable parametric data from the DUT.

To address these and other needs, aspects of this disclosure relate to a method and apparatus for detecting whether an input analog electrical signal applied to a DUT has settled, for semiconductor device testing with improved reliability, efficiency, and/or cost. The method and system may provide for providing an input signal for a device under test (DUT), monitoring the input signal, and determining if and when the input signal has settled to a reliable value. Determining whether the input signal has settled can include determining whether the measurements of the input signal remain within a sufficient number of consecutive, temporally sequential measurement windows, which can include a predetermined range of electrical signal amplitudes that can be positioned around a settle value, which represents a desired input signal amplitude. A DUT can include, but is not limited to, semiconductor device components, including packaged and unpackaged integrated circuit (IC) dies including monolithically integrated IC dies as well as bonded or stacked IC dies that include passive and/or active circuitry. Such dies can include integrated circuits, such as logic circuitry, volatile and nonvolatile memory circuitry, power delivery circuitry, photonic integrated circuitry, to name a few.

Various challenges arise in effectively monitoring input signals and determining when a settle point has been reached. Existing methods for determining when an input signal has settled (reached a settle point) can overly rely on expert human observation and analysis. While these existing methods can result in accurate determination of settle points, they can demand numerous observations and can produce predictions which can overgeneralize due to usage of conservative “buffers” to ensure settling has occurred.

To address these and other needs, the disclosed method and system includes providing a semiconductor tester a DUT, providing an input signal configured to electrically connect to the DUT, receiving measurements of the input signal, arranging the input signal measurements into measurement windows, and determining that a sufficient number of consecutive measurement windows have been observed.

### Analog Signal Settling Monitoring System

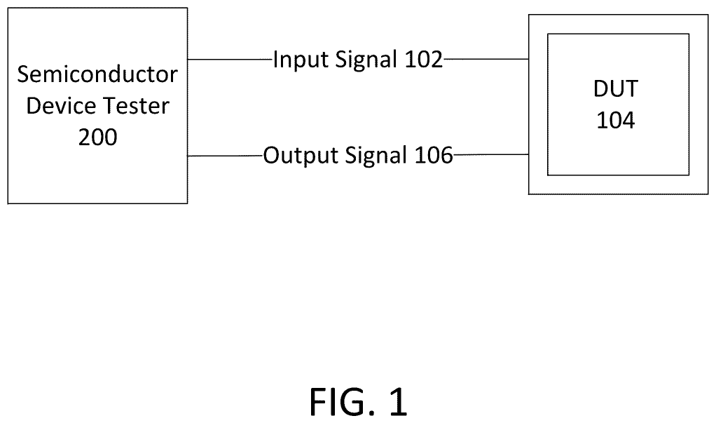

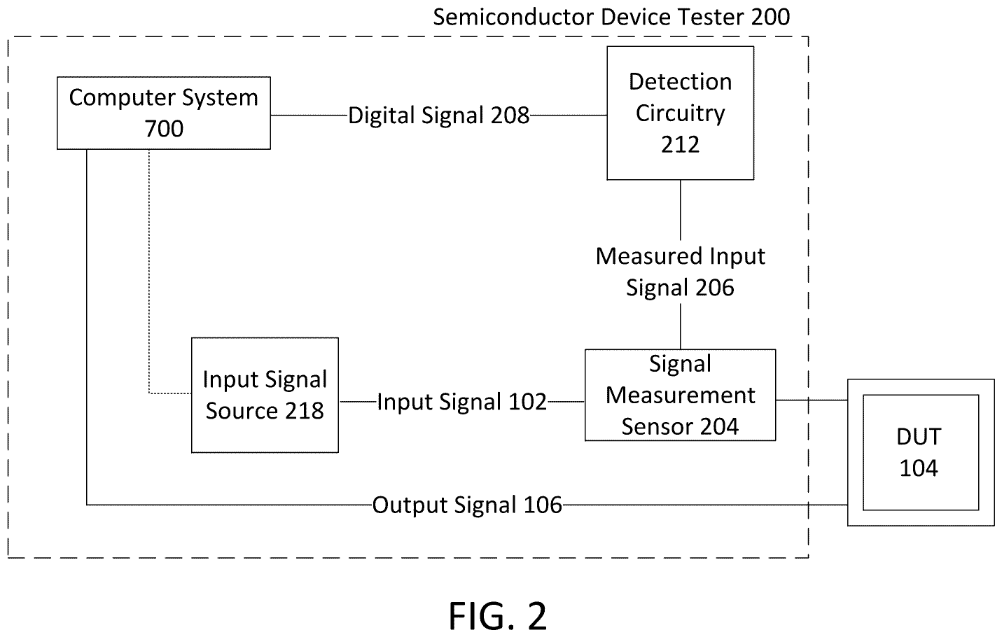

Generally, aspects of the present disclosure relate to systems and methods of monitoring an input signal for a DUT and determining if and when the input signal has settled (i.e., has reached a settle point). FIG. 1 is an illustrative example of a semiconductor device tester 200 including a device under test (DUT) 104 configured to receive an input signal 102 and output an output signal 106. FIG. 2 is an illustrative embodiment of a semiconductor device tester 200 configured for monitoring settling of an input signal and a device under test (DUT) 104 electrically connected thereto.

An electrical signal (“signal”) can be an electrical current and/or voltage provided to or received from a circuit, such as an IC device. Signals can be steady-state, oscillating, or any combination of waveforms and amplitudes. Input signals 102 are electrical signals, as are output signals. In some embodiments, electrical signals can correspond to levels of current ranging from 0.05 amps to 1000 amps. In some embodiments, electrical signals can correspond to levels of voltage ranging from 0.5 volts to 10000 volts. In some embodiments, electrical signals can correspond to levels of voltage between 1 μvolts and 1 volt. In some embodiments, electrical signals can correspond to levels of current ranging from 1 nanoamps to 1 amp.

The DUT 104 can be an integrated circuit or any other electrical device composed of silicon, another semiconductor, or a combination of semiconductors. The DUT 104 can be placed into a semiconductor device tester for various parametric testing for functionality, performance and reliability, including current, voltage, power, or any other metric. Semiconductor device testing can include electronically connecting an input signal to one or more components of the DUT 104. An input signal can be electrical current or voltage applied to, and which causes a response by, the DUT 104. The input signal 102 can be configured to cause the DUT 104 to undergo operations like computational tasks or experience conditions like specified levels of heat produced directly or indirectly by passing the input signal to and through the DUT 104. By passing an input signal to the DUT 104, a corresponding output signal 106 can be generated, wherein the output signal 106 can be an electrical signal emitted from the DUT 104 in response to an input signal being passed through the DUT 104. The input signal 102 can be received by the DUT 104 at an input terminal and the output signal 106 can be generated by the DUT 104 at an output terminal. The input signal 102 can be provided by an input signal source 218. In some embodiments, the output signal 106 can be received by the input signal source 218 or a computer system 700. Characteristics of the output signal 106 can be used to determine whether the input signal 106 has settled.

Still referring to FIG. 2, when an input signal is initially generated, there can be a time of settling, wherein the input signal can vary significantly over time until electronics and/or mechanical components internal or external to the input signal source 218 have fully adjusted to operations involved in generating the input signal. A newly generated input signal can vary due to system characteristics of the input signal source 218 such as resistance, inductance, capacitance, etc., which can cause a greater or smaller quantity of electrical signal to be generated relative to the signal that is intended. An input signal settling, or reaching a settle point, can correspond to various circuit components internal to or external to the input signal source 218 adjusting to the initial generation of the input signal. Time between an input signal being generated and settling is referred to herein as a settling time. While waiting to settle, the input signal provided to the DUT 104 can be unsuitable for reliable characterization. Unreliable input signal causes the output signal from the DUT 104 to be unreliable. Thus, properly determining when an input signal has settled can be crucial for numerous applications which are dependent upon precise signal measurements.

Measuring the input signal 102 can be performed by a suitable current or voltage measurement technique and sensor to directly measure an input signal current or voltage. For example, to measure an input signal 102, a signal measurement sensor 204 can be electrically connected to detection circuitry 212. The detection circuitry 212 can be configured to receive a measured input signal 206 from the signal measurement sensor 204.

In some embodiments, a signal measurement sensor 204 can be an ammeter serially connected to the input signal 102. In some embodiments, a signal measurement sensor 204 can be a resistor, wherein an output current from the resistor can be measured by measuring a voltage across the resistor and applying the voltage to Ohm's Law. Ohm's law can be represented by the equation: I=V/R, wherein I refers to electrical current (in this case, output current through a resistor), V refers to a voltage across a resistor, and R refers to resistance of a resistor. A voltage across a resistor can be a voltage differential between a first voltage measured at an input to the resistor and a second voltage measured at an output of the resistor.

Still referring to FIG. 2, to receive a measured input signal 206, e.g., current or voltage corresponding to an input signal 102, a signal measurement sensor 204 can be electrically connected to a detection circuitry 212. In some embodiments, the detection circuitry 212 can be an electric device configured to receive measurements from the signal measurement sensor 204. In some embodiments, the detection circuitry 212 can include a device configured to receive a first voltage and second voltage and determine a corresponding current value of an input signal 102.

In some embodiments, the detection circuitry 212 can be, or include, an analog-to-digital convertor (ADC), a device which receives analog electrical signals and generates corresponding digital signals 208, wherein digital signals 208 are binary signals capable of being received and processed by a computer processor or other integrated logic. An ADC can be composed of multiple logic gates and integrated circuits. In some embodiments, an ADC can be configured to receive a measured input signal 206 and generate a corresponding digital signal 208. In some embodiments, an ADC can be configured to receive a first voltage and second voltage from a resistor serially connected to a DUT and generate a corresponding digital signal 208.

A digital signal 208 can be received by a computer system 700 including one or more computer processors and computer-readable memory. The computer system 700 can receive the digital signal 208 and record an amplitude of the digital signal 208 onto the computer-readable memory or onto integrated circuit (“IC”) code (code held by a field-programable gate array, an application specific integrated circuit, a microsequencer, etc.) for future review and modification. Contents of the computer-readable memory may be reviewed and used for a plurality of purposes, including determining if input signal 102 measurements correspond to a settle point and for use as training data for a machine learning model.

### Settle Detection

In some embodiments, detecting when an input signal 102 has reached a settle point includes tracking a measured input signal 206 over time with sequential measurement windows which overlap the measured input signal 206; setting a settle count which can represent a number of consecutive measurement windows which have unshifted constant signal value ranges; and detecting that the tracked measured input signal 206 met or exceeded the settle count with a sufficient number of sequential measurement windows.

As used herein, a measurement window refers to a frame of analysis applied to a measured input signal 206. A measurement window spans a constant signal value range, e.g., a constant voltage range or constant current range with an upper and lower limit within which measured input signal 206 measurements are overlapped, and a constant measurement period, which can be a number of measurements of an input signal 102 or a constant unit of time having an equal number of input signal measurements. Tracking a measured input signal 206 can include applying sequential measurement windows to input signal 102 measurements by overlapping at least a portion of the input signal 102 measurements with the constant signal value range of the measurement windows, allowing placement of the input signal 206 measurements into the frame of analysis present within measurement windows.

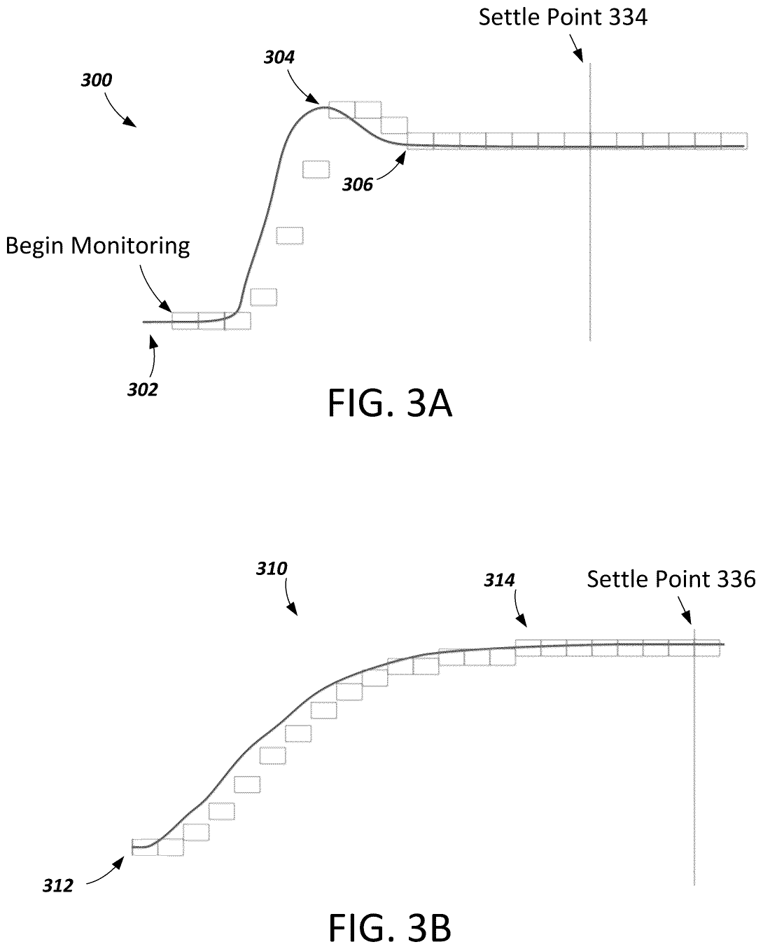

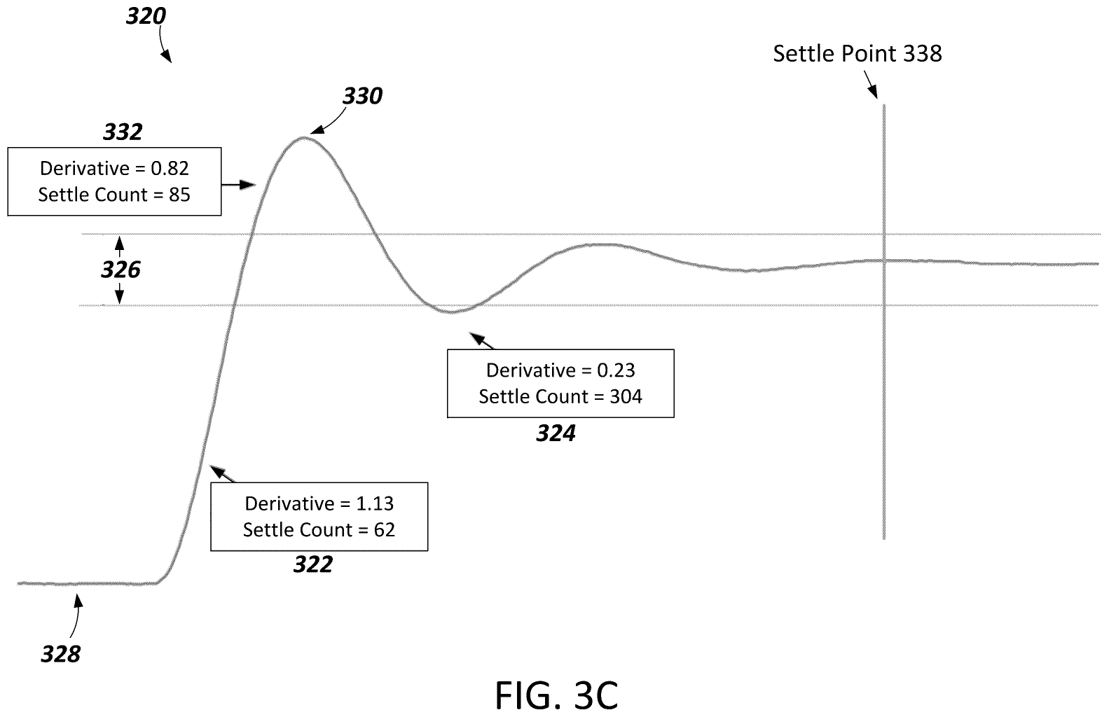

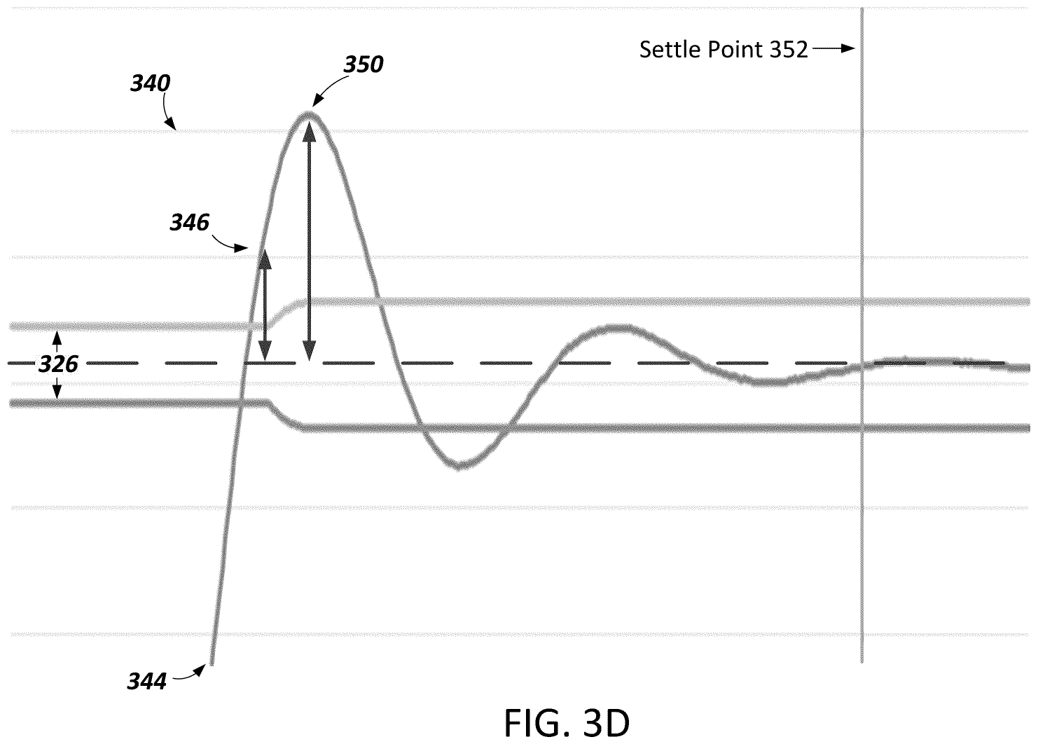

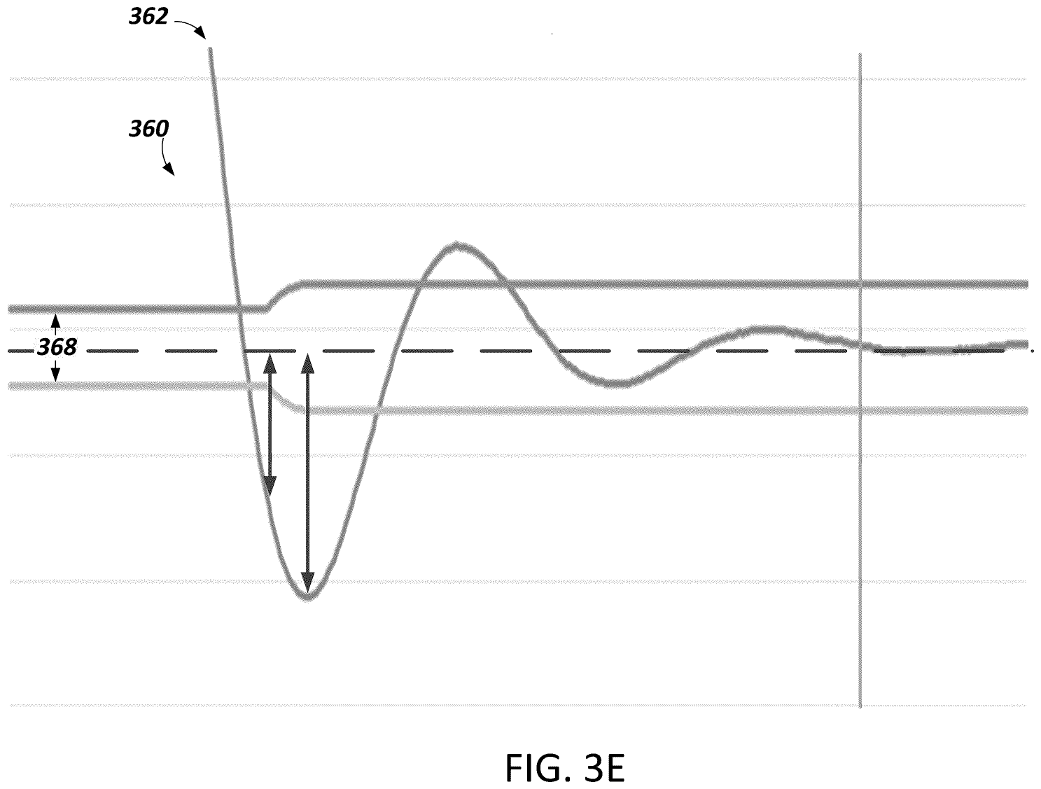

In some embodiments, the input signal measurements can be statistically represented, e.g., averaged, prior to analysis within the measurement windows. That is, measurements within a measurement window can either be raw input signal 102 measurements or a statistical representation such as an average of input signal 102 measurements. Averaging input signal measurements can lead to a reduced signal-to-noise ratio within measured input signal measurements. Tracking a measured input signal 206 can include graphically representing the measured input signal 206. When visualized on a graph, a measurement window can be square or rectangular shaped, wherein the constant measurement period can span a first graphical axis and the constant signal value range can span a second graphical axis. A first graphical axis or abscissa can correspond to a number of input signal 102 measurements or time and a second graphical axis or ordinate can correspond to input signal 102 measurements. For example, a measurement window can correspond to a constant signal value range of +/−5 mV. In this example, if a measurement window is centered around 0.5 volts, measured input signal 206 amplitudes within a measurement window can extend from 0.495 volts to 0.505 volts. Example implementations of a measurement window are illustrated in FIG. 3A, which is a graph 300 of an example measured input signal 206 in the form of an input voltage which settles relatively quickly, and in FIG. 3B, which is a graph 310 of an example measured input signal 206 in the form of an input voltage which settles relatively slowly. In the illustrated graphs 300, 310, the measurement windows are represented by consecutive rectangular boxes having a constant signal value range in the y axis of +/−12.5 mV and a constant measurement period of 4 microseconds (wherein measurements occur every 4 microseconds).

In some embodiments, the number of input signal 102 measurements within a measurement window is between 4 and 10. As a measured input signal 206 changes, the measurement windows can be continuously applied to detect potential settle points, potentially shifting in location according to changes in the measured input signal 206. Shifting of a given measurement window can be done according to changes in input signal 102 measurements so as to keep at least a portion of the input signal 102 measurements overlapped by sequential measurement windows. When a given measurement window is to be placed, the given measurement window can be shifted with respect to an immediately preceding measurement window when an input signal 206 has moved outside of a constant signal value range—referring to the range of measurement values contained by the constant signal value range—of the immediately preceding measurement window. When shifting a measurement window, shifting can be done according to changes in the input signal's location with respect to a preceding measurement window; shifting a measurement window can be proportional to changes in voltage or current value of the input signal. A measurement window can be centered around a first measured input signal 206 value and if the measured input signal 206 stays within a constant signal value range of the measurement window, consecutive measurement windows will be adjacently positioned so as to align their constant signal value ranges—without shifting along the y axis. For example, a measured input signal 206 can have an initial measured amplitude of 0.8 volts which continuously increases to 0.804 volts over the course of measurements contained within a single measurement window. In this example, if the initial measurement window is centered at 0.8 volts, because the measured amplitude remains within a constant signal value range of 0.795 to 0.805 volts, the next measurement window would remain centered around 0.8 volts for the next measurements. On the other hand, if the measured amplitude increases or decreases to a value outside of 0.795 to 0.805 volts, the next measurement window would shift so as to overlap the for the next measurements.

In some embodiments, sequential measurement windows do not overlap input signal measurements. Instead, the sequential measurement windows overlap an averaged input signal measurement value of a preceding measurement window. When a first input signal measurement is received, a first measurement window can be placed so as to be centered on the first input signal measurement. Input signal measurements within the first measurement window will be averaged and a second measurement window can be centered on the averaged value. All subsequent measurement windows can be similarly positioned according to an averaged input signal measurement value of each preceding measurement window. When the averaged measured input signal of a preceding measurement window has moved outside the limits of the preceding measurement window, a sequential measurement window can be shifted such that the sequential measurement window overlaps at least a portion of the averaged measured input signal.

Thus, in some instances (especially those in which input signal measurements increase or decrease rapidly) not all measurement windows will overlap the input signal measurements. For example, a first measurement window can be centered around 1.5 volts with a constant value range of +/−0.001 volts. Within the first measurement window, which records 8 input signal measurements, the input signal measurements can steadily raise from 1.5 volts to 4 volts, corresponding to an averaged input signal measurement of 1.8125 volts. The second measurement window can then be centered at 1.8125 volts. Notably, when the second measurement window is placed, input signal measurements are outside the constant value range of the second measurement window.

A size of a constant signal value range is to be small enough that a measured input signal 206 increasing or decreasing by a significant amount will be identified as being outside the constant signal value range, but large enough that regular signal noise will be contained within the constant signal value range.

In another example, a measured input signal 206 can have an initial measured amplitude of 0.5 volts which continuously increases to 0.503 volts across multiple measurement windows. In this example, if the measurement windows have a constant signal value range of +/−5 mV, the initial measurement window will be centered at 0.5 volts, with the constant signal value range extending from 0.495 to 0.505 volts. As the measured input signal 206 always stays within the first amplitude range (between 0.495 to 0.505 volts) , consecutive measurement windows will have unshifted constant signal value ranges (between 0.495 to 0.505 volts).

In another example, a measured input signal 206 can have an initial measured amplitude of 0.1 volts which continuously increases to 0.2 volts within a single measurement window. In this example, if the measurement windows have an amplitude range of +/−5 mV, the initial measurement window will be centered at 0.1 volts, with the amplitude range extending from 0.995 volts to 0.105 volts. As the measured input signal 206 exceeds the first amplitude range (between 0.995 volts to 0.105 volts), the next measurement window will be centered around 0.2 volts, meaning consecutive measurement windows would not have aligned predetermined ranges.

Setting a settle count can include receiving or determining a number of consecutive and unshifted measurement windows which have unshifted constant signal value ranges, wherein a number of measurement windows reaching the settle count can correspond to determining that a settle point has been reached. In some embodiments, an initial settle count can be set to a predetermined value.

In some embodiments, determining that a settle point has been reached includes detecting a settle count has been met or exceeded by the measured input signal which has been tracked by sequential measurement windows. If a number of consecutive measurement windows that are unshifted meets or exceeds a settle count, a corresponding input signal 102 can be deemed to have settled. When sequential measurement windows are applied to a measured input signal 206 and the sequential measurement windows have aligned, unshifted constant signal value ranges, a window count is incremented. As used herein, a window count can be an incremental counter which tracks how many sequential measurement windows have unshifted constant signal value ranges. A window count determines when a measured input signal 206 is settled, when the window count equals a settle count. Referring to FIGS. 3A and 3B, a success criterion of seven window counts is satisfied at the indicated settle points 334 and 336.

In some embodiments, determining that a settle point has been reached can further include determining that an otherwise determined settle point for an input signal 102 is within an expected value range of the measured input signal. An expected value range can be a numeric range around a settle value, an intended or anticipated input signal amplitude. The expected value range can be set at a size which is larger than constant signal value ranges corresponding to measurement windows applied during input signal analysis. The expected value range can have a suitable value, e.g., at least 2, 4, 8, or 16 times larger, for instance at least eight times larger, than the measurement windows, or a value in a range defined by any of these values. For example, a desired input signal 102 (a settle value) can be 5 volts and an expected value range can be +/−10 mV, corresponding to a range of 4.99 volts to 5.01 volts. In this example, a corresponding constant signal value range can be +/−1.25 mV (a range eight times smaller than the expected value range). Furthermore, in this example, for an input signal 102 to be deemed settled, input signal measurements must not only be detected within a number of sequential measurement windows having unshifted constant signal value ranges meeting or exceeding a settle count, but the input signal measurements must also be between 4.99 and 5.01 volts.

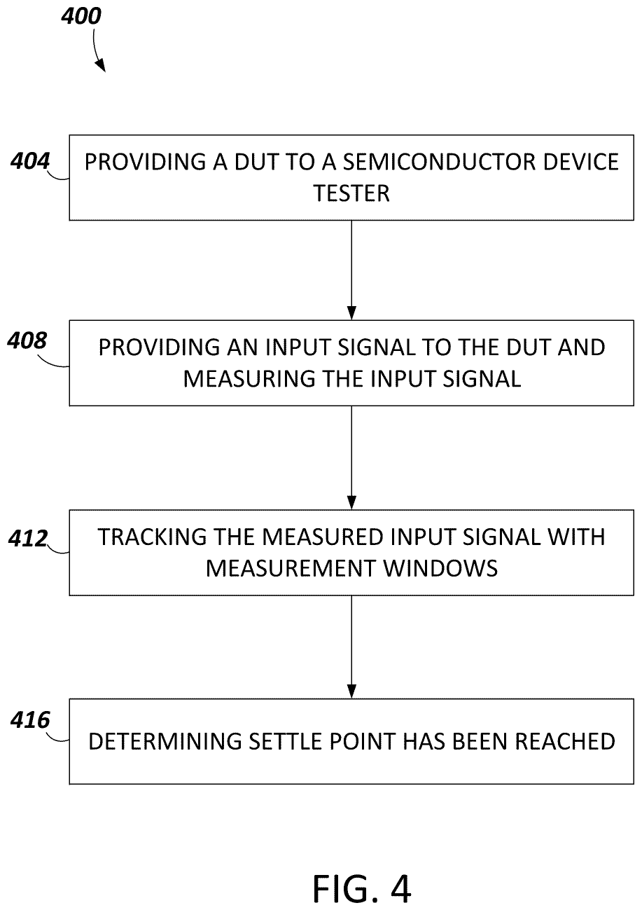

FIG. 4 is a flowchart illustrating a method of detecting settling of an analog electrical signal in semiconductor device testing, according to embodiments. The method 400 begins with step 404, providing to a semiconductor device tester a device under test (DUT). The method 400 additionally includes step 408, providing an input signal 102 to the DUT and measuring the input signal. The method 400 additionally includes step 412, tracking the measured input signal 206 over time by overlapping the measured input signal 206 with sequential measurement windows, each measurement window spanning a constant measurement period and a constant signal value range. While overlapping the measured input signal 206, the measurement windows can be shifted according to changes in the input signal 102 such that the measured input signal 206 is at least partially overlapped by the measurement windows. The method 400 additionally includes step 416, setting a settle count representing a number of consecutive and unshifted measurement windows which have unshifted constant signal value ranges, unshifted with respect to each other. The method 400 further includes determining 418 that a settle point has been reached upon detecting that the settle count has been met or exceeded by the tracked measured input signal 206.

In some embodiments, a settle value can be a quantity of amperage.

In some embodiments, a settle value can be a quantity of voltage.

In some embodiments, a settle count can be a constant value.

In some embodiments, a settle count can be between 5 and 5000.

In some embodiments, a predetermined range can be between 100μVolts and 1 volt.

In some embodiments, a predetermined range can be between 0.1 nAmps (nanoamps) to 1 mAmps (milliamps)

### Adjustable Settle Count

Input signals 102 can be relatively quickly changing or slowly changing. An input signal 102 which changes quickly experiences changes in amplitude at a comparably rapid and immediate pace, which may indicate that relatively shorter periods of input signal 102 stability may be relatively highly suggestive of long-term stability—if an input signal 102 shows it is capable of rapid and significant amplitude change, when the input signal 102 shows stability over a brief amount of time there is a relatively high degree of confidence that the input signal 102 will not experience any further significant changes. On the other hand, an input signal 102 which changes slowly experiences changes in amplitude at a comparably slow and delayed pace, which may indicate that relatively longer periods of input signal 102 stability may not be as relatively suggestive of long-term stability and can be proceeded by significant amplitude changes. That is, if a measured input signal 206 demonstrates that corresponding input signal 102 amplitude changes are slow and delayed, when the input signal 102 shows a brief period of stability there is a relatively significant possibility that the input signal 102 may experience a future, significant amplitude change. Accordingly, according to embodiments, when determining signal stability of relatively quickly changing input signals 102, a monitoring period or a settle count of windows for reaching a settle point can be set to be comparably small. On the other hand, when determining input signal 102 stability of relatively slowly changing input signals 102, a monitoring period or a settle count of windows for reaching a settle point can be set to be comparably large.

Time spent settling can range between microseconds to several seconds or more. For manufacturing and testing purposes, minimizing time a device spends waiting to be determined settled can correspond to notable increases in production efficiency. While a simple method to ensure input signal settling is to wait several minutes each time a new electric signal is introduced, such a method can be wasteful of time. Furthermore, in some embodiments, a settle count can be set once at a beginning of tracking an input signal 102.

In some embodiments, the settle count can be set a plurality of times as measurements of an input signal 102 are received. Setting the settle count can be based on a first derivative of input signal measurements through a single measurement window or sequential measurement windows. The first derivative of input signal measurements can be an equation describing a rate of change observed between the input signal measurements. A first derivative value can be used to set a new settle count. In some embodiments, the first derivative of input signal measurements can be recorded differences between adjacent input signal measurements per unit of X axis. Adjacent input signal measurements can be within a single measurement window (e.g., a first input signal measurement and a second input signal measurement can be within a first measurement window) or consecutive measurement windows (e.g., a first input signal measurement can be within a first measurement window and a second input signal measurement can be within a second measurement window). By way of an example, a first input signal measurement can be 5 volts and a subsequent measurement can be 5.1 volts. In this example, the first derivative is 0.1 volts/unit of X axis (e.g., measurement or time). In another example, a first input signal measurement can be 6.2 volts and an adjacent measurement can be 6.1 volts. In this example, the first derivative is 0.1 volts/unit of X axis (the first derivative is always positive because it is a measurement of absolute change, all measured first derivatives will be positive).

In some embodiments, a first derivative can be generated in relation to averaged input signal measurements across subsequent measurement windows. For example, an averaged input signal measurement in a first window can be 5.1 volts (a summed value of all input signal measurements in the first window divided by the number of measurements) and an averaged input signal measurement in a second window can be 5.3 volts. In this example, the first derivative can be 0.2 volts/unit of X axis.

In some embodiments, when monitoring of an input signal begins, the settle count can be first set to an initial settle count and continuously or periodically updated a plurality of times based on a relationship that is inversely proportional to a first derivative of input signal measurements within one or more measurement windows. For example, an initial settle count can be set at a predetermined value. In this example, the first derivative can be determined based on the input signal 102 measured within a given measurement window, within a plurality of measurement windows, or for a duration during which the input signal 102 is settling. As an input signal 102 is measured, a first derivative of the measured input signal 206 amplitude can be recorded and used to reset a settle count. As the first derivative of the input signal 102 increases as measurement windows are applied, a settle count can be decreased as the measurement progresses. For example, an initial settle count can be set to 10. In this example, if a first derivative is 5 V/measurement, a new settle count of 7 can be generated. In another example, if a first derivative is 3 V/measurement, a new settle count of 9 can be generated.

In some embodiments, updating a settle count can involve only increasing the settle count according to a relationship that is inversely proportional to a first derivative of input signal measurements within one or more settle windows. As the first derivative decreases, a corresponding settle count can be increased. However, in this embodiment, once a settle count is set at a given value, the settle count cannot be reduced below that value, unless the input signal measurements enter and exit the expected value range 326, after which a settle count can be reset to an initial settle count value and updated according to newly determined first derivates (further described later).

In some embodiments, the settle count can be set based on whether the measured input signal 206 is within an expected value range 326. For example, a settle count can be held constant while a measured input signal 206 is within an expected value range 326 around a settle value. An expected value range 326 can be an amplitude range centered around a settle. For example, a settle value can be 0.1 volts and an amplitude range for an expected value range 326 can span +/−5 mV. In this example, while measured input signal 206 measurements fall between 0.995 volts and 0.105 volts, a corresponding settle count will be held content.

In some embodiments, if a measured input signal 206 amplitude moves from inside to outside an expected value range 326, either with an amplitude greater or less than the expected value range 326, a settle count can be updated according to a new first derivative of input signal measurements. A portion of measured input signal measurements which lie wholly above or below the expected value range 316 is referred to herein as a segment.

In some embodiments, the expected value range is between +/−0.001 volts and +/−1,000 volts.

In some embodiments, the settle count can be set a plurality of times and can be based on a proportional relationship with an amount of time taken for input signal measurements to proceed from an initial value to a threshold percentage of a settle value. In such embodiments, input signal measurements begin at a value lower than the settle value and generally increase while settling. The amount of time taken for the input signal measurements to reach the threshold percentage of the settle value can be multiplied by a constant to generate a second settle count. If the second settle count is larger than the current settle count, the settle count can be updated to the second settle count. The aforementioned embodiments can apply during a first segment, e.g., until input signal measurements reach an expected value range. After the first segment, the settle count can be held constant, or the settle count can be set according to the inverse relationship with the derivative of the input signal measurements.

In some embodiments, the threshold percentage can be 90%.

### Application of Signal Settling Detection

Detection of a settle point can be applied to machine learning applications. In some embodiments, the method can include a learning mode, wherein various input signal factors can be presented and modified to seek optimization of one or more output signal factors. Input signal factors can include bandwidth setting, range setting (e.g., a resistance value applied in a circuit controlling the input signal), and capacitance (within the circuit controlling the input signal). The output signal factors determined by the learning mode can include a shorter settle time (when comparing two or more sets of input signal factors) and whether overshooting or undershooting a settle value is acceptable. By grouping the input signal factors with the output signal factors, the learning mode can be used to generate datasets capable of training machine learning models to predict output signal factors when presented with input signal factors.

In some embodiments, learning mode can include a computer system 700 electrically connected to an input signal source 218 and configured to cause generation of a plurality of input signals with varying input signal factors and receive and record corresponding digital signals. As input signal factors are applied to generate input signals, corresponding digital signals can be received and associated with the input signal factors to build a dataset.

By training a machine learning model on a dataset derived from the learning mode, the machine learning model can be used to select input signal features which optimally achieve desired output signal factors. For example, a user may have a desired output, an output signal which settles at 0.5V and which does not overshoot an expected value range. The user can then present the machine learning model with a plurality of input signal factors, review output signal factors generated by the machine learning model, and select a set of input signal factors which most closely match their desired output.

In some embodiments, a machine learning model can be trained on a dataset derived from the learning mode so as to enable to machine learning model to be presented with desired output signal factors and can generate a set of input signal factors which are predicted to achieve the desired output signal factors.

### Signal Settling Monitoring System

FIG. 1 is an illustrative embodiment of a semiconductor device tester 200 having loaded therein a device under test (DUT) 104 being electrically coupled to an input signal 102 signal and an output signal 106.

The semiconductor device tester 200 can be a suitable mechanical and/or electrical system for testing one or more aspects of the DUT 104. For example, an aspect of the DUT 104 being tested by a semiconductor device tester 200 can be current flowing to and from the DUT 104 at specific input voltages and maximum clock speed and maximum clock speed while exposed to high or low temperatures, or any other test. In some embodiments, a semiconductor device tester 200 can be automatic test equipment.

The DUT 104 can be any integrated circuit device or any other electronic device capable of being tested by a semiconductor device tester 200. A DUT can commonly be an integrated circuit (IC) device, which is a device manufactured of one or more semiconductors and designed to receive one or more input signals 102 and perform a task, whether processing, computation, or some other operation.

Within the semiconductor device tester 200, the DUT 104 can be electrically coupled to an input signal 102, which can be an electrical signal corresponding to a quantity of voltage and current which can expose the DUT 104 to a test and/or cause the DUT 104 to perform a function. The input signal 102 can be steady-state or variable (for example, a wave function). A DUT 104 can also have an electrically coupled output signal 106, an electrical signal corresponding to an input signal 102 having passed through the DUT. An output signal 106 can be of a similar character as a corresponding input signal 102 in terms of amplitude and signal shape, although the input signal 102 will tend to be lower in amplitude than a corresponding input signal 102, but this is not always the case.

FIG. 2 illustrates an example embodiment of a semiconductor device tester 200 having received therein a DUT 104 according to embodiments. A signal measurement sensor 204 is electrically connected to the input signal 102 and a corresponding measured input signal 206 is generated by the signal measurement sensor 204. Detection circuitry 212 is electrically connected to the measured input signal 206 so as to receive a measurement of the input signal 102 and generate a corresponding digital signal 208 received by a computer system 700 electrically connected to the detection circuitry 212. As a whole, the hardware contained within FIG. 2 can be used to perform a method of monitoring an input signal 102 for settling.

The DUT 104, as further described elsewhere in the application, can be an electric device which undergoes one or more tests within a semiconductor device tester 200. The DUT 104 can be an integrated circuit (IC) device, which is an electric device formed in a semiconductor, and which can be used to perform or assist computational processes.

The input signal 102 can be provided by an input signal source 218. In some embodiments, the output signal 106 can be received by a computer system 700. An input signal source 218 can be any source of electrical power, including but not limited to: one or more batteries, a generator, a circuit electrically connected to an electrical power grid, or any other source. In some embodiments, the output signal 106 can be received by a computer system 700, whereby the output signal 106 can be interpreted and processed directly by the computer system 700.

The signal measurement sensor 204 can be a suitable device for measuring current, e.g., an ammeter serially connected to the input signal, a resistor with a measurable resistivity that can carry electrical current, or another electrical device for measuring electrical voltage or current. The signal measurement sensor 204 can have an input terminal, corresponding to where an electric signal is fed into the signal measurement sensor 204, and an output terminal, corresponding to where an electric signal leaves the signal measurement sensor 204.

To measure an input signal 102 across a resistor, a the detection circuitry can be electrically connected to an input terminal and output terminal of the signal measurement sensor 204. The first input terminal can correspond to a first voltage and the output terminal can correspond to a second voltage. In embodiments when the signal measurement sensor includes a resistor, dividing a difference between the first and second voltage by a resistance value of the resistor will produce a level of electric current being carried through the resistor. Together, the first voltage and second voltage compose the measured input signal 206.

The detection circuitry 212 can be electrically connected to a measured input signal 206 from the signal measurement sensor 204. Detection circuitry 212 can be one or more electric devices which can receive a measured input signal 206 and generate a digital signal 208 corresponding to the measured input signal 206. Detection circuitry 212 can be/include an analog-to-digital converter, an electric device which can receive an analog signal and generate a corresponding digital signal 208 as an output.

Digital signals 208 can be received and recorded by a computer system 700 electrically connected to the detection circuitry 212. A computer system 700 can include one or more processors and computer-readable memory.

FIG. 3A is a graph 300 of an example measured input signal 206 which settles relatively quickly and a method of determining when a settle point is reached. In this example, a settle count is 7.

The measured input signal 206 begins at a first amplitude at 302, where analysis by application of measurement windows begins shortly after the measured input signal 206 is received. The measurement windows have an amplitude range of +/−12.5 mV, e.g., if the averaged measured input signal 206 varies by no more than 12.5 mV from a voltage measured at a start of a measurement window, a consecutive measurement window will be adjacently positioned without shifting along the y-axis and a window count will be incremented towards a settle count. The measured input signal 206 quickly increase in amplitude to a maximum value at 304 and then quickly decreases to a stable amplitude at 306. As is shown, when the measured input signal 206 experiences amplitude stability at 306, the measured input signal 206 experiences no further significant amplitude changes. As is shown, the amplitude range of the first measurement window applied after the measured input signal 206 reaches stability at 306 contains all future input signal amplitudes and thus, a settle point 334 is reached soon after stability is reached. In total, the measured input signal 206 achieved a settle count of 7 after 16 applied measurement windows.

As is shown, as the measured input signal 206 is monitored, multiple measurement windows do not overlap the measurements. This is due to measurement windows (apart from the first placed measurement window) being positioned based upon an average of input signal 102 measurements from a previous measurement window. In multiple instances, after input signal 102 measurements are averaged in a first measurement window, the resulting average value is used to center a second measurement window while the input signal 102 measurements are outside of the second measurement window. This is why between point 302 and 304 the measurement windows do not overlap the input signal 102 measurements in several instances.

FIG. 3B is a graph 310 of an example measured input signal 206 which settles relatively slowly and a method of detecting when a settle point occurs. The measured input signal 206 begins at a first amplitude 312 and gradually increases to a final amplitude 314 range. Notably, 22 measurement windows were applied before a settle point 336 was reached with a corresponding settle count of 7. Thus, a relatively slowly changing measured input signal 206 can correspond with a longer necessary monitoring period to detect a settle point.

FIG. 3C is a graph 320 depicting an example measured input signal 206 with a settle count being set as measurements progress. The measured input signal 206 begins at a first amplitude 328, increases rapidly to a second amplitude 330 and then cycles downward and upward in amplitude until reaching a settle point 338. An expected value range 326 is shown, implicitly centered around a settle value. The expected value range 316 is a range of value centered around an expected settle value. In some embodiments, the expected value range 316 is +/−20 mV. Portions of a measured input signal 206 which lie below or above the expected value range 316 are referred to as segments. When adjusting a settle count, a first derivative of the measured input signal is determined in relation to measurements received within a corresponding segment. When a measured input signal 206 is initially received, an initial settle count is set and updated according to an inverse relationship to identified first derivative of measured input signals 206. If measurements of the input signal enter an expected value range, the settle count is held constant until the corresponding input signal 102 either settles or measurements extend above or below the expected value range. Upon exiting the expected value range, the measured input signal 206 enters a new segment, wherein the settle count is reset to the initial settle count, a new first derivative of input signal measurements is identified, and the settle count is once more updated according to an inverse relationship with the first derivative of the input signal measurements. The settle count can be set multiple times as multiple first derivatives are received, where each first derivative measurement corresponds to a different settle count. In some embodiments, a settle count can be increased within a single segment. Received first derivatives within a single segment which correspond to a lower settle count may not affect the settle count.

In FIG. 3C, a portion of the measured input signal 206 between the first amplitude 328 and the expected value range 326 is a first segment 322; the portion of the measured input signal 206 which extends above the expected value range 326 is a second segment 332; and a portion of the measured input signal 206 which extends briefly below the expected value range 326 before reentering the expected value range 326 is a third segment 324. Within the first segment 322, a derivative of measured input signal 206 values is 1.13 (e.g., volts/unit of X axis or amperage/unit of X axis) and an initial settle count is correspondingly updated to account for the first derivative, resulting in a settle count of 62. When the measured input signal 206 traverses from the first segment 322 into the expected value range 326, the settle count is held constant at 62 and remains so while the measured input signal 206 remains within the expected value range 326. When the measured input signal 206 leaves the expected value range 326 and enters the second segment 332, the settle count is reset to an initial value, a new first derivative of measured input signal 206 values is generated, and the settle count is set as the first derivative changes within the second segment 332. A calculated first derivative in the second segment 332 is 0.82, corresponding to a settle count of 85. As the measured input signal 206 enters the expected value range 326 from the second segment 332, the settle count of 85 is kept constant and remains so while the measured signal remains within the expected value range 326. When the measured input signal 206 exits the expected value range 326 and enters the third segment 324, the settle count is once again reset to an initial value, a new first derivative of measured input signal 206 values is generated, and the settle count is set as the first derivative changes within the third segment 324. A calculated first derivative in the third segment 324 is 0.23, corresponding to a settle count of 304. Once the measured input signal 206 enters the expected value range 326 from the third segment 324, the measured input signal 206 stays within the expected value range 326 until reaching a settle point 338. Noticeably, Throughout settling, as the first derivative decreased, the settle count increased, corresponding to an input signal 102 changing relatively slowly having a larger settle count and a longer settle time.

FIG. 3D is a graph 340 depicting an example measured input signal 206 with an expected value range 326 being set as measurement progresses and the measured input signal undershoots a settle value. Similarly to FIG. 3C, the measured input signal 206 begins at a first amplitude 344, increases rapidly to a second amplitude 350 and then cycles downward and upward in amplitude until reaching a settle point 352. An expected value range 326 is shown, implicitly centered around a settle value. In the illustrated specific example, the expected value range 326 is +/−0.152V. When adjusting an expected value range 326, an amount of overshoot (during instances in which the measured input signal 206 has an initial value less than the expected value range 326) is determined in relation to a difference between the measured input value 206 and an expected settle value (the center of the expected value range). When a measured input signal 206 is initially received, an initial expected value range 326 is set and updated according to a proportional relationship to the identified difference between the measured input value 206 and the expected settle value. If the difference, accounting for the proportional relationship, exceeds the size of the expected value range 326, the expected value range 326 can be increased according to the difference.

In FIG. 3D, when the measured input signal 206 reaches the point 346, the difference between the measured input signal 206 and the settle value, accounting for the proportional relationship, begins to exceed the expected value range 326. After point 346, the expected value range 326 is increased until the measured input signal 206 reaches a peak value at 350, after which the expected value range 326 remains constant.

In some embodiments, a proportional relationship, e.g., a percentage relationship, between the expected value range 426 and the identified difference between the measured input value 206 and the settle value, can exist. By way of example, in the illustrated example, the difference is 25%. In this example, when a value corresponding to 25% of the difference between the measured input value 206 and the settle value exceeds the expected value range 326, the expected value range 326 will be updated to the value. For example, an expected value range can be +/−0.152V centered around an expected value of 2.57V, and the proportional relationship can be 25% of the difference between the measured input value 206 and the settle value. In this example, when the measured input signal 206 is 3.57V, the difference is 1V and after applying the 25% proportional relationship, a value of 0.25V results. Since the resulting 0.25V is larger than the initial 0.152V expected value range, the expected value range is set to +/−0.25V.

When a measured input signal 206 is first received with a value less than the expected value range 326, only instances of overshooting the expected value range 326 can increase the size of the expected value range 326. When a measured input signal 206 is first received with a value greater than the expected value range 326, only instances of undershooting the expected value range 326 can increase the size of the expected value range 326.

FIG. 3E is a graph 360 depicting an example measured input signal 206 with an expected value range 368 being set as measurement progresses and the measured input signal undershoots a settle value. FIG. 3E is a graph 360 depicting an example measured input signal 206 with an expected value range 368 being set as measurements progress and undershoot a settle value. FIG. 3E is a similar example to that depicted in FIG. 3D, except setting the expected value range 368 is based upon an amount of undershoot, determined in relation to a difference between the expected settle value and the measured input value 206.

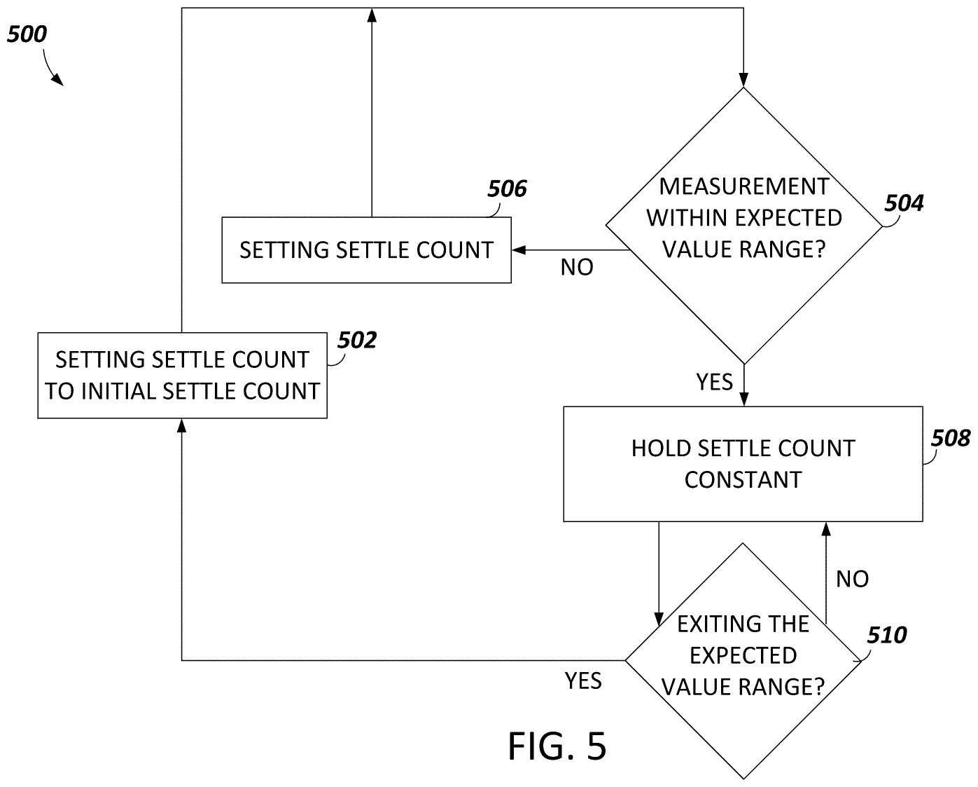

FIG. 4 is a flowchart illustrating a method of detecting settling of an analog electrical signal in semiconductor device testing, according to embodiments. The method 400 begins with step 404, providing to a semiconductor device tester a device under test (DUT) 104. The method 400 additionally includes step 408, providing an input signal 102 to the DUT 104 and measuring the input signal. An input signal 102 can be provided by an input signal source 218 electrically coupled to the DUT 104. An input signal source 218 can be any source of electrical power, including but not limited to: one or more batteries, a generator, a circuit electrically connected to an electrical power grid, or any other source. In some embodiments, the input signal source 218 can be electrically connected to a computer system 700 configured to cause the input signal source 218 to generate one or more input signals 102. The method 400 additionally includes step 412, tracking the measured input signal over a period of time by overlapping the measured input signal 206 with sequential measurement windows, wherein each sequential measurement window may be shifted according to changes in the input signal 102 so as to at least partially overlap the input signal 102. A measurement window is an analytical framework containing a range of signal amplitude values and a number of input signal measurements. Step 412 also includes receiving an initial settle count, a number of consecutive unshifted measurement windows which have unshifted constant signal value ranges with respect to each other. The method 400 further includes determining 416 that a settle point has been reached upon detecting that a number of sequential, unshifted measurement windows meets the settle count. In some embodiments, the settle count can be set by a method 500 described herein with respect to FIG. 5. When a settle point has been detected, a corresponding digital signal 208 can be generated and received by the computer system 700.

FIG. 5 is a graph 500 illustrating a method of detecting settling of an analog electrical signal in semiconductor testing with a settle count set as measurements progress and which accommodates an expected value range 326. At step 502, a computer system 700 or integrated circuit (e.g., a microprocessor, field-programmable-gate-array, application specific integrated circuit, etc.) running a finite state machine (“FSM”) begins to execute the method of detecting settling of an analog electrical signal, which includes setting a settle count to an initial settle count value, receiving measured input signal 206 values, and determining a first derivative between measured input signal 206 values. At step 504, the method can determine if the measured input signal 206 lies within an expected value range.

If the measured input signal 206 is not within the expected value range, the method moves to step 506, wherein the first derivative (an absolute value of a difference between consecutive input signal 102 measurements or averaged input signal measurements in adjacent measurements windows) is used to update a settle count. A settle count can be set based on a relationship that is inversely proportional to the first derivative of input signal measurements within a segment—where each first derivative can update the settle count according to the inverse relationship, but in some embodiments the settle count can only be increased within a single segment, meaning a settle count will always be updated according to a first derivative. After step 506, the method can proceed back to step 504.

If, at step 504, a measured input signal 206 is located within an expected value range, the method proceeds to step 508, wherein a settle count will be held constant for every measurement that stays within the expected value range 326 and can be used to detect settling in step 416 of the method 400 (FIG. 4).

From step 508, the method proceeds to step 510, wherein the method determines if the measured input signal 206 value is exiting the expected value range 326. If the input signal measurement is not exiting the expected value range 326, the method proceeds back to step 508 where the settle point will be held constant and monitoring for a settle point will continue.

If, at step 510, the measured input signal is determined to be leaving the expected value range 326, the method proceeds back to step 502, wherein the settle count can be set to the initial settle count value and a first derivative between input signal measurements of 0 can be recorded. The method 500 can proceed from Step 502 as previously described.

The method 500 will terminate when a settle point is reached (step 416 of method 400).

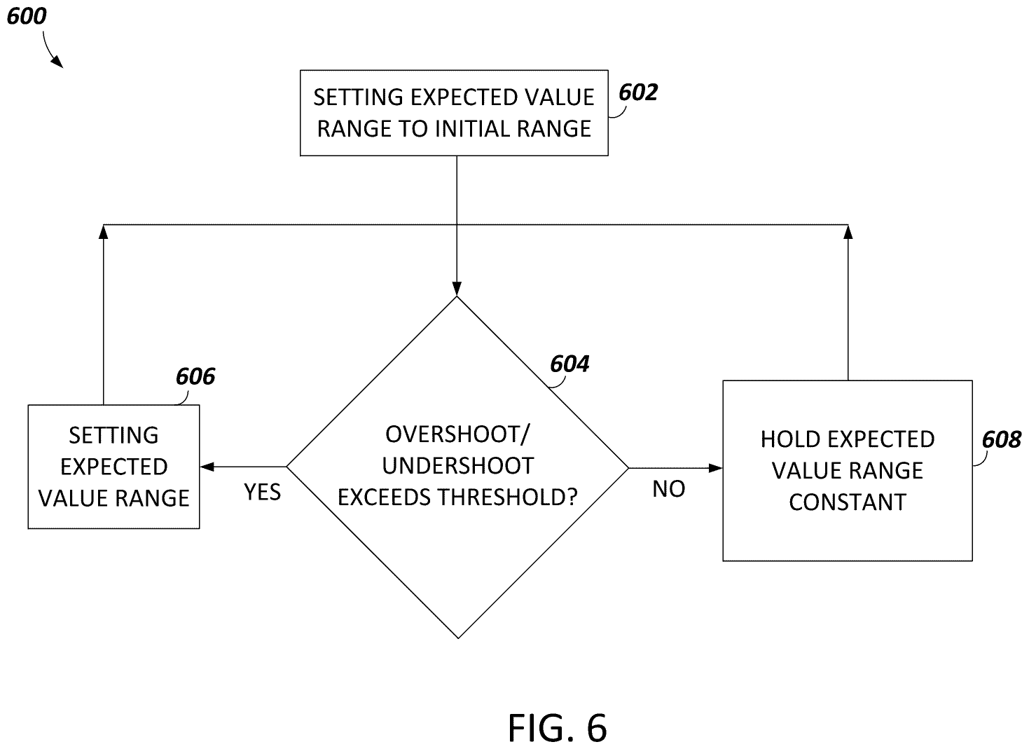

FIG. 6 is a graph 600 illustrating a method of detecting settling of an analog electrical signal in semiconductor testing with an expected value range 326 set as measurements progress. At step 602, a computer system 700 begins to execute the method of detecting settling of an analog electrical signal, which includes setting an expected value range 326 to an initial value, receiving measured input signal 206 values, and recording/updating quantities of overshooting and undershooting a settle value (the center of the expected value range 326). At step 604, the method can determine if a measured overshoot or undershoot meets a threshold. The threshold accounts for a proportional relationship between an observed amount of overshooting or undershooting. In some embodiments, the proportional relationship can be 25% of the overshoot/undershoot if a resulting quantity is greater than the present expected value range 326.

If the measured overshoot/undershoot (accounting for the proportional relationship) exceeds the current expected value range 326, the method moves to step 606, where the measured overshoot/undershoot is used to update the expected value range 326. After step 606, the method can proceed back to step 604.

If, at step 604, the measured overshoot/undershoot (accounting for the proportional relationship) does not exceed the current expected value range 326, the method moves to step 608, where the expected value range can be held constant. After step 608, the method can proceed back to step 604.

The method 600 will terminate when a settle point is reached (step 416 of method 400).

In some embodiments, dynamically setting the expected value range 326 as input signal 206 measurements are received depends upon whether measurements initially are less than or greater than a settle value.

### Computer System

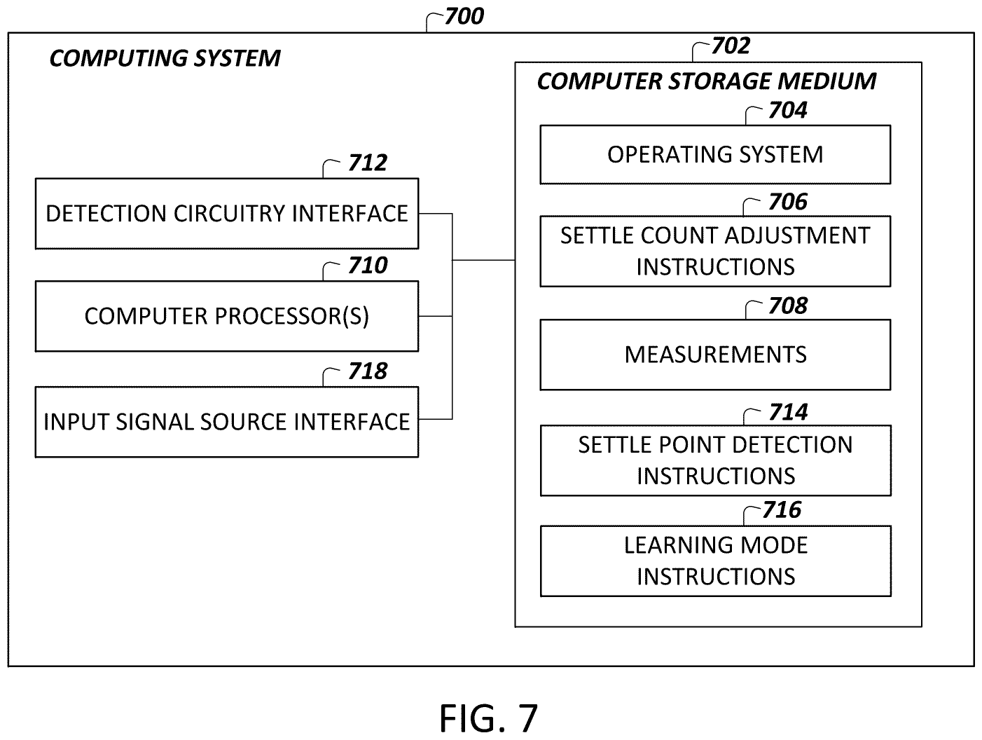

FIG. 7 illustrates an example computer system 700 that may be used in some embodiments to execute the processes and methods and implement the features described above. In some embodiments, the computer system 700 may include: one or more computer processors 710, such as physical central processing units (“CPUs”), embedded CPUs, or graphics processing units (“GPUs”); non-transitory computer storage medium 702, such as high density disks (“HDDs”), solid state drives (“SDDs”), flash drives, and/or other persistent non-transitory computer storage media; an detection circuitry interface 712, such as an IO interface in communication between an analog-to digital converter and the computer system 700; and/or an input signal source interface 718, such as an IO interface in communication between an input signal source 218 and the computer system 700, wherein the IO interface can control generation of input signals 102.

The non-transitory computer storage medium 702 may include computer program instructions that the computer processor 710 executes in order to implement one or more embodiments. The non-transitory computer storage medium 702 can store an operating system 704 that provides computer program instructions for use by the computer processor 710 in the general administration and operation of the computer system 700. The non-transitory computer storage medium 702 can also include settle count adjustment instructions 706 for receiving a input signal 206 measurements, generating a first derivative, and modifying a corresponding settle count. The non-transitory computer storage medium 702 can include settle point detection instructions 714 for applying measurement windows to a measured input signal 206 and detecting when a quantity of consecutive measurement windows equals or exceed a settle count. The non-transitory computer storage medium 702 can include learning mode instructions 716 for applying a series of input signals 102 to a DUT in a semiconductor device tester 200 with differing parameters (e.g., voltage, amperage, wavelength, etc.). The non-transitory computer storage medium 702 can also include measurements 708 of measured input signals 206 deriving from received digital signals 208, including identification of first derivatives of measured input signals.

### Terminology

Depending on the embodiment, certain acts, events, or functions of any of the processes or algorithms described herein can be performed in a different sequence, can be added, merged, or left out altogether (e.g., not all described operations, sequencing, or events are necessary for the practice of the algorithm). Moreover, in certain embodiments, operations or events can be performed concurrently, e.g., through multi-threaded processing, interrupt processing, or multiple processors or processor cores or on other parallel architectures, rather than sequentially.

The various illustrative logical blocks, modules, routines, and algorithm steps described in connection with the embodiments disclosed herein can be implemented as electronic hardware, or combinations of electronic hardware and computer software. To clearly illustrate this interchangeability, various illustrative components, blocks, modules, and steps have been described above generally in terms of their functionality. Whether such functionality is implemented as hardware, or as software that runs on hardware, depends upon the particular application and design constraints imposed on the overall system. The described functionality can be implemented in varying ways for each particular application, but such implementation decisions should not be interpreted as causing a departure from the scope of the disclosure.

Moreover, the various illustrative logical blocks and modules described in connection with the embodiments disclosed herein can be implemented or performed by a machine, such as a computer processor device, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A computer processor device can be a microprocessor, but in the alternative, the processor device can be a controller, microcontroller, or state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, routine, or algorithm described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer storage medium. An exemplary storage medium can be coupled to the processor device such that the processor device can read information from, and write information to, the storage medium. In the alternative, the storage medium can be integral to the processor device. The processor device and the storage medium can reside in an ASIC. The ASIC can reside in a user terminal. In the alternative, the processor device and the storage medium can reside as discrete components in a user terminal.

In several instances, the phrase (or phrases analogous to) “record” is used. In context of this disclosure, “record” and “recording” can refer to preserving a numerical value on a computer-readable medium—e.g., the aforementioned RAM memory, flash memory, ROM memory, EPROM memory, EEPROM memory, registers, hard disk, a removable disk, a CD-ROM, or any other form of a non-transitory computer storage medium, or integrated circuit —e.g., onto a microsequencer, FPGA, ASIC, or any other IC device. Setting a value to be equal to a different value can include updating a first recorded numerical value to be identical to a second recorded numerical value.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without other input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or”means one, some, or all of the elements in the list.

Disjunctive language such as the phrase “at least one of X, Y, Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C.

While the above detailed description has shown, described, and pointed out novel features as applied to various embodiments, it can be understood that various omissions, substitutions, and changes in the form and details of the devices or algorithms illustrated can be made without departing from the spirit of the disclosure. As can be recognized, certain embodiments described herein can be embodied within a form that does not provide all of the features and benefits set forth herein, as some features can be used or practiced separately from others. The scope of certain embodiments disclosed herein is indicated by the appended claims rather than by the foregoing description. All changes which come within the meaning and range of equivalency of the claims are to be embraced within their scope.

What is claimed is:

1. A method of detecting settling of an analog electrical signal in semiconductor device testing, the method comprising:
providing in a semiconductor device tester a device under test (DUT);
providing an input signal to the DUT and measuring the input signal;
tracking the measured input signal over time with sequential measurement windows that do not overlap with each other,
wherein each measurement window spans a constant measurement period and a constant signal value range while shifting according to changes in the measured input signal such that each measurement window overlaps at least a portion of the measured input signal corresponding to a preceding measurement window;
setting a settle count representing a number of consecutive and unshifted measurement windows having unshifted constant signal value ranges; and
determining that a settle point has been reached upon detecting that the settle count has been met or exceeded by the measured input signal tracked by the sequential measurement windows.

2. The method of claim 1, wherein the constant measurement period is a constant period of time during which a constant number of measurements are made.

3. The method of claim 1, wherein the constant signal value range is a constant voltage range or a constant current range.

4. The method of claim 1, wherein shifting of a given measurement window according to changes in the measured input signal comprises shifting when the measured input signal during the given measurement window has moved outside the constant signal value range of the given measurement window immediately preceding the given measurement window.

5. The method of claim 1, wherein tracking the measured input signal over time with sequential measurement windows comprises centering a first measured input value over the measured input signal.

6. The method of claim 1, wherein shifting of a given measurement window according to changes in the measured input signal comprises shifting when an averaged measurement input signal during the given measurement window has moved outside the constant signal value range of the given measurement window.

7. The method of claim 4, wherein shifting of the given measurement window according to changes in the input signal comprises shifting proportionally to changes in voltage or current values of the input signal.

8. The method of claim 1, wherein setting the settle count comprises determining a first derivative of the measured input signal and setting the settle count based on a relationship that is inversely proportional to the first derivative of the input signal measurements.

9. The method of claim 8, further comprising setting the settle count a plurality of times based on changing first derivatives of the input signal measurements across the sequential measurement windows.

10. The method of claim 9, wherein determining that the settle point has been reached further comprises determining that the settle point is within an expected value range of the measured input signal.

11. The method of claim 8, wherein the first derivative of input signal measurements comprises a difference between adjacent input signal measurements per unit of X axis.

12. The method of claim 9, wherein the settle count can only be increased.

13. The method of claim 10, wherein the first derivative is set to 0 and the settle count is set to an initial settle count when the measured input signal exits the expected value range from inside the expected value range.

14. The method of claim 10, wherein setting the settle count a plurality of time only occurs when the measured input signal is outside the expected value range.

15. The method of claim 1, wherein tracking comprises graphically representing the measured input signal, and wherein the constant measurement period spans a first graphical axis and the constant signal value range spans a second graphical axis.

16. The method of method of claim 10, further comprising setting the expected value range a plurality of times based on a relationship that is proportional to an amount of overshoot between the input signal measurements and an expected settle value and a threshold value.

17. The method of claim 10, further comprising setting the expected value range a plurality of times based on a relationship that is proportional to an amount of undershoot between the input signal measurements and an expected settle value and a threshold value.

18. A semiconductor testing apparatus configured for detecting settling of an analog electrical signal during semiconductor device testing, the apparatus comprising:
a semiconductor device tester configured to receive therein a device under test (DUT);
an input signal source configured to provide an input signal to the DUT and a signal measurement sensor configured to measure the input signal, the signal measurement sensor configured to monitor for settling of an electrical signal by directly measuring the input signal;
a detection circuitry configured to receive a measured input signal from the signal measurement sensor; and
a non-transitory computer storage medium storing instructions that when executed by one or more processors, causes the one or more processors to perform operations comprising:
tracking the measured input signal over time with sequential measurement windows that do not overlap with each other,
wherein each measurement window spans a constant measurement period and a constant signal value range while shifting according to changes in the measured input signal such that each measurement window overlaps at least a portion of the measured input signal corresponding to a preceding measurement window;
setting a settle count representing a number of consecutive and unshifted measurement windows having unshifted constant signal value ranges; and
determining that a settle point has been reached upon detecting that the settle count has been met or exceeded by the measured input signal tracked by the sequential measurement windows.

19. The apparatus of claim 18, wherein the signal measurement sensor is an ammeter, or a resistor directly serially connected to the device under test.

20. The apparatus of claim 18, wherein the detection circuitry is an analog-to-digital converter.

21. The apparatus of claim 18, wherein the detection circuitry is electrically connected to a computer system electrically connected to an input signal source configured to supply an input signal to a device under test.

22. A non-transitory computer storage medium storing instructions that when executed by one or more processors, cause the one or more processors to perform operations comprising:
detecting in a semiconductor device tester a device under test (DUT) provided therein;
providing an input signal to the DUT and measuring the input signal;
tracking the measured input signal over time with sequential measurement windows overlapping the measured input signal,
wherein each measurement window spans a constant measurement period and a constant signal value range while shifting according to changes in the input signal a first measurement window overlaps a first measured input signal value and consecutive measurement windows overlap an averaged value of input signal measurements of each preceding measurement window;
setting a settle count representing a number of consecutive and unshifted measurement windows having unshifted constant signal value ranges; and
determining that a settle point has been reached upon detecting that the settle count has been met or exceeded by the measured input signal tracked by the sequential measurement windows.

23. The non-transitory computer storage medium of claim 22, wherein setting the settle count comprises measuring a first derivative of input signal measurements within a measurement window and setting the settle count based on a relationship that is inversely proportional to the first derivative of input signal measurements within the measurement window.

24. The non-transitory computer storage medium of claim 22, wherein the operations further comprise setting the settle count a plurality of times based on changing first derivatives of the input signal measurements across the sequential measurement windows.

25. The non-transitory computer storage medium of claim 22, wherein determining that the settle point has been reached further comprises determining that the settle point is within an expected value range of the measured input signal.

26. The non-transitory computer storage medium of claim 23, wherein the first derivative of input signal measurements comprises a recorded difference between consecutive input signal measurements per unit of X axis within a measurement window.

27. The non-transitory computer storage medium of claim 22, wherein tracking comprises graphically representing the measured input signal, and wherein the constant measurement period spans a first graphical axis and the constant signal value range spans a second graphical axis.
